(19) United States
(12) Patent Application Publication
(10) Pub. No.: US 2016/0225919 A1
(43) Pub. Date: Aug. 4, 2016

(54) DEVICE STRUCTURE WITH NEGATIVE RESISTANCE CHARACTERISTICS

(71) Applicant: GLOBALFOUNDRIES INC., GRAND CAYMAN (KY)

(72) Inventors: Fen Chen, Williston, VT (US); Carole D. Graas, Jericho, VT (US); Terence L. Kane, Wappinger Falls, NY (US); Michael A. Shinosky, Jericho, VT (US)

(21) Appl. No.: 14/612,639

(22) Filed: Feb. 3, 2015

(51) Int. Cl. H01L 29/94; H01L 29/32

(52) U.S. Cl. CPC H01L 29/945; H01L 29/32

(57) ABSTRACT

Device structures that exhibit negative resistance characteristics and fabrication methods for such device structures. A signal is applied to a metal layer of a metal-insulator-semiconductor capacitor to cause a breakdown of an insulator layer of the metal-insulator-semiconductor capacitor at a location. The breakdown at the location of the insulator layer causes the metal-insulator-semiconductor capacitor to exhibit negative resistance. The metal layer may be comprised of a polycrystalline metal. A grain of the polycrystalline metal may penetrate through the insulator layer and into a portion of a substrate at the location of the breakdown.

### BACKGROUND

The present invention relates to semiconductor device fabrication and, more specifically, to device structures that exhibit negative resistance characteristics and fabrication methods for such device structures.

Certain devices exhibit negative resistance in which an increase in voltage across the device's terminals is observed to result in a decrease in electric current through it. The behavior of a device that exhibits negative resistance contrasts with the behavior of a common resistor. A common resistor exhibits positive resistance in which an increase of applied voltage causes a proportional increase in current due to Ohm's law. While a resistor consumes power from current passing through it, a negative resistance device may produce power or may even be used to amplify an electrical signal.

Improved device structures that exhibit negative resistance characteristics and fabrication methods for such device structures are needed.

### SUMMARY

According to an embodiment of the invention, a method is provided for forming a device structure. The method includes fabricating a metal-insulator-semiconductor capacitor using a substrate comprised of a semiconductor and applying a signal to a metal layer of the metal-insulator-semiconductor capacitor to cause a breakdown of an insulator layer of the metal-insulator-semiconductor capacitor at a location and thereby form the device structure. The breakdown at the location of the insulator layer causes the device structure to exhibit negative resistance.

According to another embodiment of the invention, a device structure is formed using a substrate comprised of a semiconductor. The device structure includes a first layer comprised of a polycrystalline metal, the polycrystalline metal including plurality of grains and a second layer comprised of an electrical insulator. The second layer is positioned between the first layer and a portion of the substrate. At least one of the grains penetrates through the second layer and into the portion of the substrate

### BRIEF DESCRIPTION OF THE SEVERAL VIEWS OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIG. 1 is a cross-sectional view of a device structure in accordance with an embodiment of the invention.

FIG. 2 is an enlarged view of a portion of FIG. 1.

FIG. 3 is a current-voltage graph illustrating the current through a device structure, formed in accordance with an embodiment of the invention, as a function of applied voltage when biased in inversion mode during operation in an integrated circuit.

FIG. 4 is a current-voltage graph illustrating a device structure being programmed in accordance with an embodiment of the invention.

FIG. 5 is a diagrammatic view of an exemplary computer system configured to program a device structure consistent with the embodiments of the invention.

FIG. 6 is a cross-sectional view of a device structure in accordance with an alternative embodiment of the invention.

FIG. 7 is a graphical representation showing the programming of different device structures in accordance with an embodiment of the invention.

FIG. 8 is a graphical representation showing the performance of different device structures that have been programmed in accordance with an embodiment of the invention.

FIG. 9 is a secondary-electron micrograph showing a portion of a programmed device structure.

### DETAILED DESCRIPTION

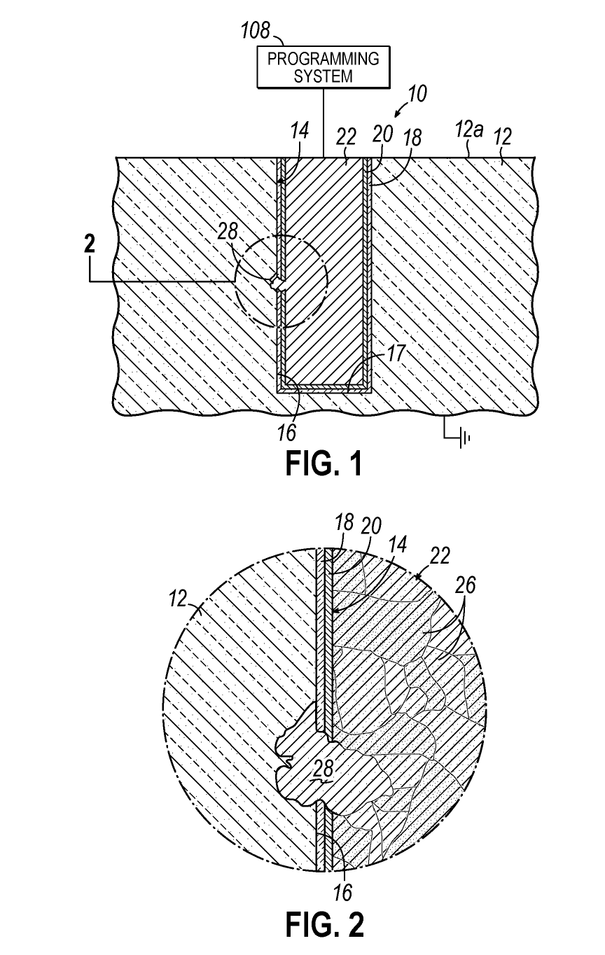

With reference to FIGS. 1, 2 and in accordance with an embodiment of the invention, a device structure 10 is formed in a substrate 12 that may be comprised of a semiconductor material, such as single crystal silicon or another single crystal semiconductor material that contains primarily silicon, and that may include an epitaxial layer at its top surface 12a. The semiconductor material of the substrate 12 may include a p-type impurity species selected from Group III of the Periodic Table (e.g., boron) that is effective to impart p-type conductivity. Alternatively, the semiconductor material of the substrate 12 may be doped by introducing an electrically-active dopant, such as an n-type dopant from Group V of the Periodic Table (e.g., phosphorus (P) or arsenic (As)) that is effective to impart n-type conductivity.

A trench 14 is formed in the substrate 12 and includes one or more sidewalls 16 that extend from the top surface 12a of the substrate 12 to a given depth into the substrate 12. The trench 14 may have a depth in a range from 5 micron (μm) to 100 μm, and may have an opening size with dimensions that are selected to provide a given layer thicknesses for layers subsequently formed in the trench 14. If the trench 14 is round in vertical cross-section so as to have the shape of a right-circular cylinder, the opening size is represented by the diameter of a circle. Alternatively, the trench 14 may have a different geometrical shape, such as a square, rectangular, or a V-shape with openings of corresponding shapes characterized by respective opening sizes.

The trench 14 may be formed by forming an etch mask with photolithography, and, with the patterned mask present, then using a wet chemical etching process or a dry etching process (e.g., reactive-ion etching (RIE)) to define the trench 14. The etch mask may comprise a coating of a light-sensitive material, such as a photoresist, that is applied by a spin coating process, pre-baked, exposed to light projected through a photomask, baked after exposure, and developed with a chemical developer to form the etch mask. The etch mask includes an opening at the intended location for trench 14. The etch mask protects the covered regions of the substrate 12 against etching. The etching process relies on a given etch chemistry to etch the material of the uncovered region of the substrate 12 coinciding with the opening in the etch mask. After the trench 14 is formed, the etch mask is removed (e.g., by ashing or solvent stripping if the etch mask is comprised of photoresist), followed by a process that cleans the top surface 12a of the substrate 12 before further processing.

An insulator layer 18 may be formed on the one or more sidewalls 16 of the trench 14. The insulator layer 18 may be comprised of an electrical insulator material, such as a high-k dielectric (e.g., hafnium dioxide (HfO₂)) deposited by atomic layer deposition (ALD) or an oxide of silicon like silicon dioxide (SiO₂) formed by oxidation or chemical vapor deposition (CVD). In an embodiment, the insulator layer 18 may be comprised of an oxide of silicon deposited by CVD using tetraethylorthosilicate (TEOS) as a precursor compound, and may have a thickness in a range of 100 nm to 1000 nm. Oxide thicknesses for the insulator layer 18 in this range are greater than thicknesses for the insulator in a typical metal-oxide-semiconductor (MOS) capacitor. The enhanced thickness of the insulator layer 18 may be selected based upon breakdown characteristics of the constituent insulator material in order to assure a proper programming condition for negative resistance generation during programming

A liner layer 20 may be formed on the insulator layer 18 covering the one or more sidewalls 16 of the trench 14. In specific embodiments, the liner layer 20 may be comprised of titanium (Ti), titanium nitride (TiN), tantalum (Ta), tantalum nitride (TaN), or a multilayer combination of these materials. In one embodiment, the liner layer 20 may be comprised of a bilayer of Ta/TaN having a total thickness ranging from 50 nm to 200 nm. The liner layer 20 may be deposited using, for example, physical vapor deposition (PVD). After the insulator layer 18 and liner layer 20 are formed, the majority of the space inside the trench 14 remains unfilled.

After the liner layer 20 is formed, a plug 22 may be formed as a layer on the one or more sidewalls 16 and base 17 of the trench 14 in order to fill the remaining space inside the trench 14 that is not noccupied by the insulator layer 18 and liner layer 20. The plug 22 may be comprised of a metal, such as copper (Cu), which may be polycrystalline and which may include a plurality of crystalline grains 26 that meet along grain boundaries. The plug 22 may have a layer thickness in a range of 1 micron (μm) to 15 μm, which depends on the opening size of the trench 14. The grain size of the grains 26 may increase with increasing layer thickness. The liner layer 20 promotes the adhesion of the metal comprising the plug 22 to the insulator layer 18 and may function to prevent atomic diffusion from the metal of the plug 22 into the insulator layer 18. The insulator layer 18 and the liner layer 20 are arranged between the plug 22 and the portion of the substrate 12 adjacent to the sidewall 16 of the trench 14.

The plug 22 may be provided by a metal layer that adopts the geometrical shape of the trench 14. The metal layer may totally fill the trench 14 or, alternatively, may only partially fill the trench 14 (e.g., the plug 22 may have a hollow core). The metal layer may be comprised of Cu, although other suitable low-resistivity metals and metal alloys may be selected for the composition of the plug 22. The metal layer may be deposited by a deposition process, such as an electrochemical plating process like electroplating, that does not generate a thick overburden of metal on the top surface 12a of the substrate 12. A thin seed layer comprised of the metal may be deposited using, for example, physical vapor deposition (PVD) to coat the insulator layer 18. In such an electrochemical plating process, the seed layer inside the trench 14 operates as a catalyst to nucleate the plating of the metal layer. The plating conditions and/or layer thickness may be adjusted such that the grains of the polycrystalline metal have a large average grain size (e.g., a range of 1 μm to 5 μm). The layer thickness characterizing the plug is related to the dimensions of the trench 14 as the metal grows inwardly from the surfaces of the seed layer coating the liner layer 20. After the plug 22 is formed, extraneous material from the insulator layer 18, the liner layer 20, and/or the plug 22 may be removed from the top surface 12a of the substrate 12 by, for example, planarizing with chemical mechanical polishing (CMP).

One or more of the grains 26, such as the representative grain 28, extend outwardly from the plug 22 to penetrate through the liner layer 20 and the insulator layer 18 into a portion of the substrate 12 at a breakdown location of the insulator layer 18 formed during the programming process. The representative grain 28 protrudes through the sidewall 16 of the trench 14 so as to project into the portion of the semiconductor material of the substrate 12 adjacent to the trench 14. The representative grain 28 retains electrical continuity with the remainder of the plug 22 inside the trench 14.

The device structure 10 has the form of a metal-insulator-semiconductor (MIS) capacitor that has been modified as a result of programming, as discussed hereinbelow. If the insulator layer 18 is comprised of silicon dioxide, then the MIS capacitor may be characterized as a MOS capacitor that has been modified as a result of programming The device structure 10 exhibits negative resistance due at least in part to the existence of the grain 28 and, in an alternative embodiment, additional grains like the representative grain 28.

In an alternative embodiment, additional trenches may be formed and used to form additional device structures, each structured like device structure 10 and formed like device structure 10. These device structures may be arranged in an array (e.g., a 2×2 array, a 3×3 array, a 4×4 array, etc.) and wired together in parallel or in series to form, in the aggregate, a composite device structure. The ability to adjust the array size may promote an ability to tune the I/V peak-to-valley ratio (PVR) of the negative resistance by adjusting the array size.

Because the device structure is formed in a trench 14, the device structure 10 is generally vertical and includes a major dimension that is oriented or aligned normal to the plane of the top surface 12a of the substrate 12. This compact three-dimensional footprint may conserve the surface area consumed by device structure 10 and/or an array of the device structures 10 to increase the amount of surface area on top surface 12a that may be used for other high density applications. The fabrication of the device structure 10 is also silicon process compatible, which may ease fabrication.

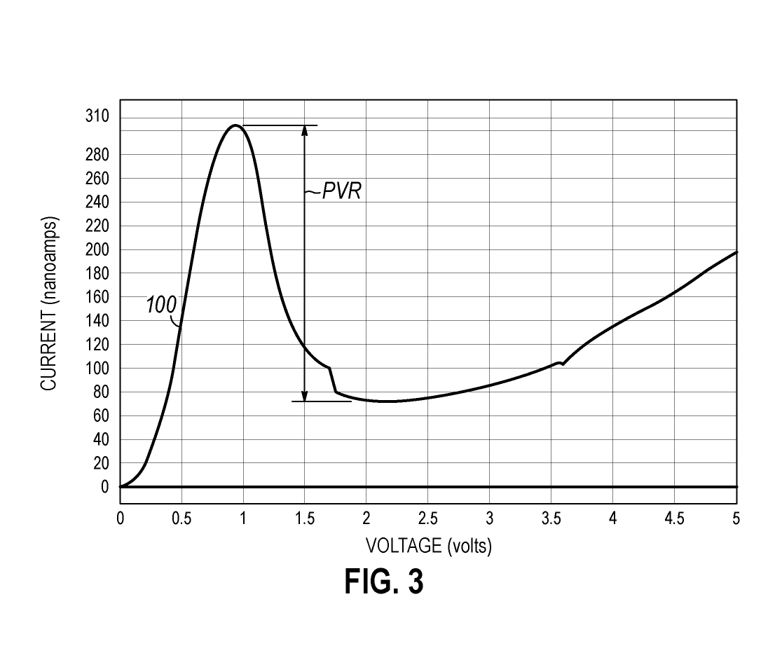

With reference to FIG. 3, the device structure 10 may exhibit a negative resistance when biased in inversion mode. The negative resistance may be attributed to the presence one or more grains 26 characterized by the physical attributes of the representative grain 28. Negative resistance refers to static resistance, which is governed by Ohm's law (R=V/I), with a direct current supplied to the device structure 10. The device structure 10 may also negative differential resistance, which refers to dynamic resistance in which the resistance is given by the instantaneous change of voltage with current (R=dV/dI) and which may be relevant with respect to time-varying currents.

When biased in inversion mode, a positive voltage may be applied to the plug 22 that is greater than the inversion threshold voltage of the device structure 10. When the positive voltage is applied to the plug 22, the substrate 12 may be grounded. As the positive voltage increases from 0 volts in the current-voltage curve 100, the leakage current increases up to an inflection point at a given threshold voltage. For applied voltages above the inflection point, the leakage current decreases with increasing voltage over a range of positive voltages as a consequence of the device structure 10 exhibiting a negative resistance. At the upper limit of this voltage range, another inflection point occurs at a given applied voltage and the leakage current again begins to increase with increasing voltage. The IN peak-to-valley ratio (PVR) between the inflection points of curve 100 (i.e., within the voltage range over which the leakage current decreases with increasing voltage) may be in a range of 1.25 to 4 at room temperature.

The negative resistance may exhibited for operation of the device structure 10 in inversion mode without actively cooling the device structure 10. Specifically, the device structure 10 may be at room temperature or an operating temperature within a circuit that exceeds room temperature, rather than cooled to a temperature that is significantly less than room temperature (e.g., liquid nitrogen temperatures). Without wishing to be limited by theory, the negative resistance may be caused by defect assisted resonant tunneling at the breakdown location(s) of the insulator layer 18. If current is considered to be the independent variable and for a given range of currents, then an increase in the current entering the plug 22 of the device structure 10 will result in a decrease in the voltage across the device structure 10. The device structure 10 may be incorporated as a functioning element in an integrated circuit, such as a temperature controllable oscillator, a binary digital output for an analog circuit, or another logic circuit or microwave circuit, and may provide functionality when the integrated circuit is powered and in normal operation.

The device structure 10 differs from a standard MOS capacitor or MIS capacitor due to modification resulting from the device programming A MOS capacitor or MIS capacitor operating as a functional element in a circuit will not include an electrode in which a portion (e.g., a grain) of the metal forming the electrode projects or penetrates through the insulator layer at a breakdown location. The result is a defective capacitor that is shorted such that charge cannot be stored on its electrodes.

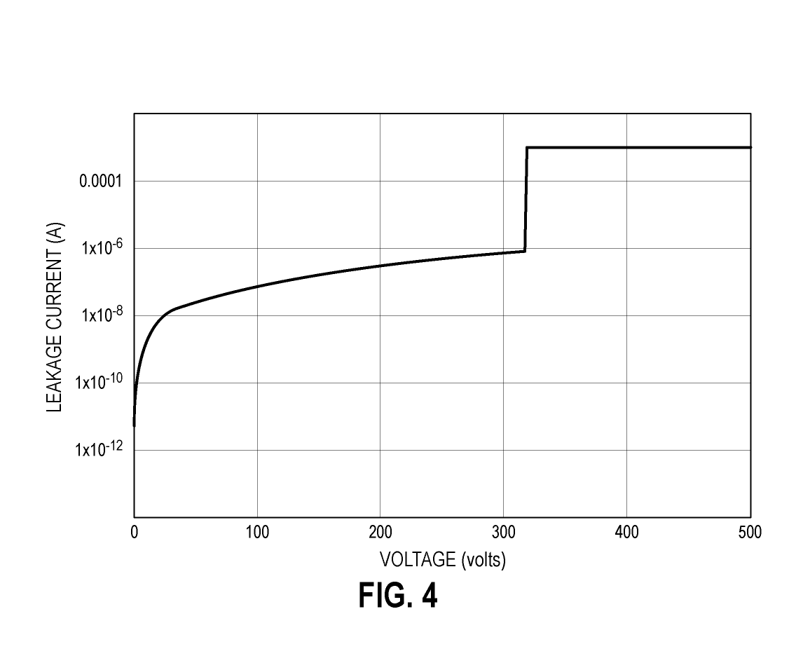

With reference to FIG. 4, the device structure 10 may be programmed under accumulation mode to modify the as-fabricated device structure 10 such that the current-voltage profile exhibits a negative resistance over a given voltage range while operating in inversion mode in a circuit. When programmed in accumulation mode, a signal characterized by a negative peak voltage that is less than the flatband voltage (i.e., the difference between the work functions of materials of the substrate 12 and the plug 22) may be applied to the plug 22. Such peak voltages are at least two orders of magnitude less than the flatband voltage. To tailor the programming conditions, the thickness of the insulator layer 18 and the grain size of the plug 22 may be selected to elevate the breakdown voltage exhibited by the device structure. In one embodiment, a signal with a peak voltage greater than or equal to 200 volts may be used to program the device structure 10. These programming voltages and peak voltages are significantly greater than operating voltages (i.e., 10 volts or less) for powering an integrated circuit in normal operation.

The programming may be implemented using different procedures. In an embodiment and as shown in FIG. 4, the device structure 10 may be programmed under accumulation mode using a signal with a ramped programming voltage having a peak voltage greater than or equal 200 volts. The programming of the device structure 10 coincides in FIG. 4 with a rapid rise in the leakage current. In an alternative embodiment, the device structure 10 may be programmed under accumulation mode using a signal with a pulsed programming voltage having a peak voltage that is greater than or equal 400 volts.

The high dissipation energy at the programming voltage may cause all or a portion of one or more grains to extrude from the plug 22 and extend through the liner layer 20 and insulator layer 18 into the semiconductor material of the substrate 12. The high dissipation energy, which that promotes the breakdown of the insulator layer 18 at each location characterized by a projecting grain 28, may be selected through, among other parameters, the selection of specific metal deposition conditions and/or the selection of the layer thickness for the insulator layer 18.

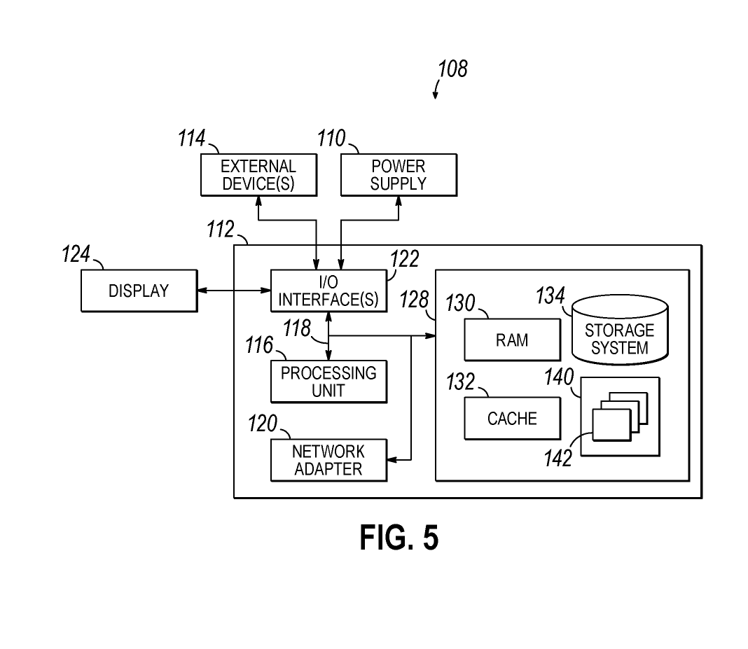

With reference to FIG. 5, a programming system 108 may include a power supply 110 and a computer system 112. The programming system 108 is configured to generate the voltage signals used to program the device structure 10 under accumulation mode. To that end, the power supply 110 is coupled with the device structure 10 and operated to produce the ramped programming voltage and/or the pulsed programming voltage in response to program code executed by the computer system 112, user interaction with the computer system 112, and/or other commands received at the computer system 112.

The computer system 112 may include one or more processors or processing units 116, a system memory 128, and a bus 118 that couples various system components including system memory 128 to each processing unit 116. Bus 118 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system 112 typically includes a variety of computer system readable media. Such media may be any available media that is accessible by computer system 112, and it includes both volatile and non-volatile media, removable and non-removable media.

System memory 128 can include computer system readable media in the form of volatile memory, such as random access memory (RAM) 130 and/or cache memory 132. Computer system 112 may further include other removable/non-removable, volatile/non-volatile computer system storage media. By way of example only, storage system 134 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM, or other optical media can be provided. In such instances, each can be connected to bus 118 by one or more data media interfaces. As will be further depicted and described below, system memory 128 may include at least one program product having a set (e.g., at least one) of program modules that are configured to carry out the functions of embodiments of the invention.

A program 140, having a set (at least one) of program modules 142, may be stored in system memory 128 by way of example, and not limitation, as well as an operating system, one or more application programs, other program modules, and program data. Each of the operating system, one or more application programs, other program modules, and program data or some combination thereof, may include an implementation of a networking environment. Program modules 142 generally carry out the functions and/or methodologies of embodiments of the invention as described herein.

In general, the routines executed to implement the embodiments of the invention used to program the device structure 10, whether implemented as part of the operating system or a specific application, component, program, object, module or sequence of instructions, or even a subset thereof, may be referred to as “computer program code,” or simply “program code.” Program code typically comprises computer readable instructions that are resident at various times in various memory and storage devices in a computer and that, when read and executed by one or more processors in a computer, cause that computer to perform the operations necessary to execute operations and/or elements embodying the various aspects of the embodiments of the invention used to program the device structure 10. Computer readable program instructions for carrying out operations of the embodiments of the invention may be, for example, assembly language or either source code or object code written in any combination of one or more programming languages.

Computer system 112 may also communicate with one or more external devices 114, such as the power supply 110, a keyboard, a pointing device, a display 124, etc.; one or more devices that enable a user to interact with computer system 112; and/or any devices (e.g., network card, modem, etc.) that enable computer system 112 to communicate with one or more other computing devices. Such communication can occur via Input/Output (I/O) interfaces 122. Still yet, computer system 112 can communicate with one or more networks such as a local area network (LAN), a general wide area network (WAN), and/or a public network (e.g., the Internet) via network adapter 120. As depicted, network adapter 120 communicates with the other components of computer system 112 via bus 118. It should be understood that although not shown, other hardware and/or software components could be used in conjunction with computer system 112. Examples, include, but are not limited to: microcode, device drivers, redundant processing units, external disk drive arrays, RAID systems, tape drives, and data archival storage systems, etc.

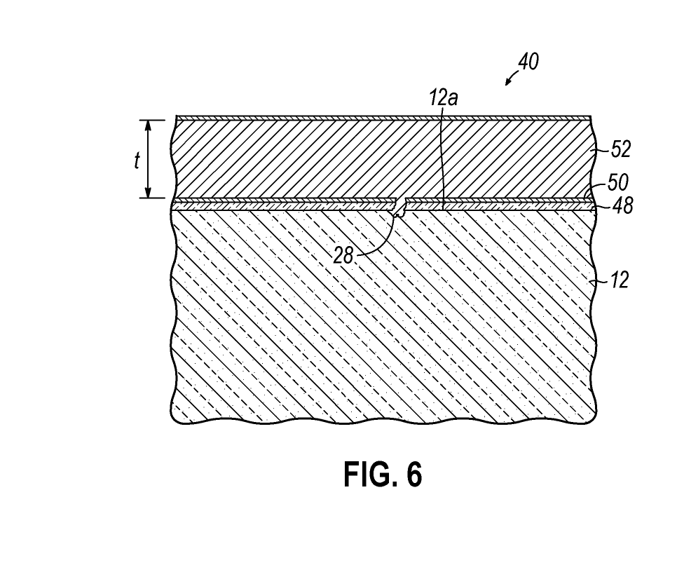

With reference to FIG. 6 in which like reference numerals refer to like features in FIG. 1, a device structure 40 is similar to the device structure 10 but includes components that are arranged in a planar configuration instead of a vertical configuration inside a trench. Specifically, the device structure 40 includes an insulator layer 48 similar to insulator layer 18, a liner layer 50 similar to liner layer 20, and a metal layer 52 that is similar to the metal layer operating as plug 22. The insulator layer 48, liner layer 50, and metal layer 52 of the device structure 40 are serially deposited on the top surface 12a of the substrate 12 and, after deposition, have top and bottom surfaces that are contained in parallel planes relative to each other and to the top surface 12a. The device structure 40 may be formed by patterning the layers 48, 50, 52 with photolithography and etching processes.

The planar MOS capacitor or MIS capacitor embodied in device structure 40 may be programmed, as described hereinabove, such that the device structure 40 exhibits negative resistance and/or negative differential resistance, as also described hereinabove. For example, the metal layer 52 may have layer thickness a in a range of 1 μm to 15 μm, which may promote relatively large grains (e.g., a grain size in a range of 1 μm to 5 μm) in the polycrystalline texture compared with smaller film thicknesses.

Further details and embodiments of the invention will be described in the following example.

A series of device structures similar to device structure 10 were fabricated in a series of arrays of different sizes. The device structures in each array included a metal electrode (i.e., a deep trench plug) comprised of copper with a thickness of 15 μm, a liner layer comprised of a bilayer of TaN(25 nm)/Ta(75 nm), and silicon dioxide with a nominal thickness of 500 nm comprising the insulator layer.

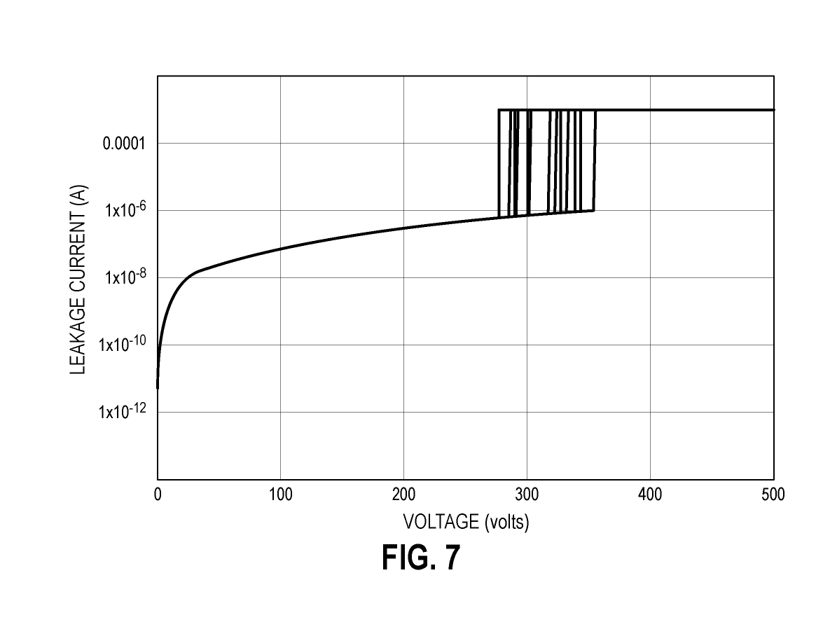

The device structures were programmed under accumulation mode using a ramped programming voltage at 125° C. with 1 volt per second ramp rate from 0 V as shown in FIG. 7. The negative voltage was applied to the metal electrode inside trench with the substrate grounded. An abrupt increase in leakage current was observed when the programming voltage causes the insulator layer for one of the device structures in an array to breakdown. At the location of the breakdown, an extruded grain of the metal electrode was caused to penetrate through the insulator layer and the liner layer into the semiconductor material of the substrate. The breakdown voltages for the insulator layer of the device structures shown in FIG. 7 are distributed in a range of about 260 volts to 360 volts for different devices under testing (DUTs) depending on their actual insulator thicknesses.

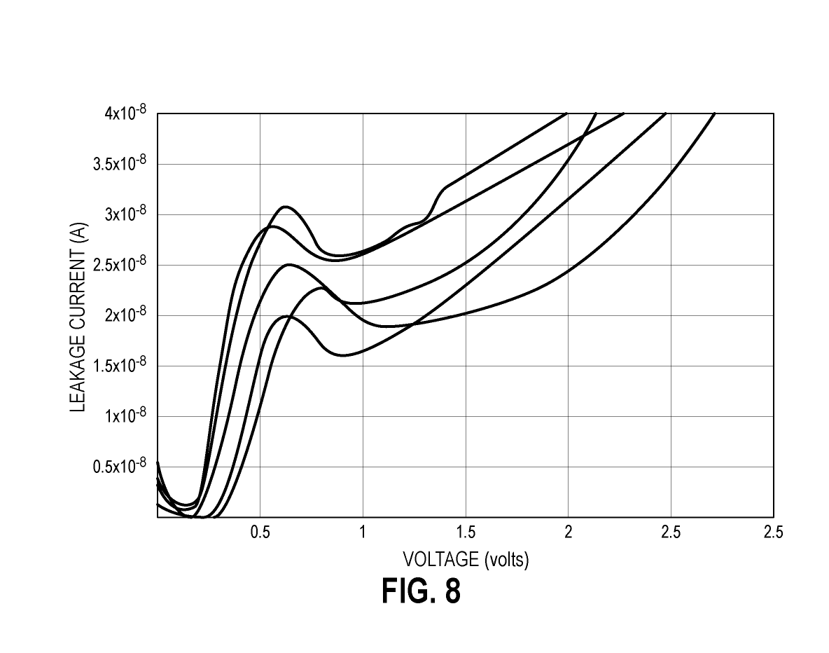

As shown in FIG. 8, the arrays of programmed devices structures exhibited negative resistance when tested under inversion mode at room temperature. Under testing, a positive voltage greater than the inversion threshold voltage was applied to the metal electrode of each device structure in the array and the electrode supplied by the substrate was grounded. As the positive voltage was increased from 0 volts, the leakage current was observed to increase up to an inflection point near 0.5 volts. At the inflection point, the leakage current began to decrease with increasing voltage over a voltage range of less than or equal to 0.5 volts positive. At the upper limit of the voltage range, another inflection point occurs and the leakage current begins to again increase with increasing voltage. The device structure is observed to exhibit negative resistance over the voltage range as evidenced by the decrease in leakage current with increasing voltage.

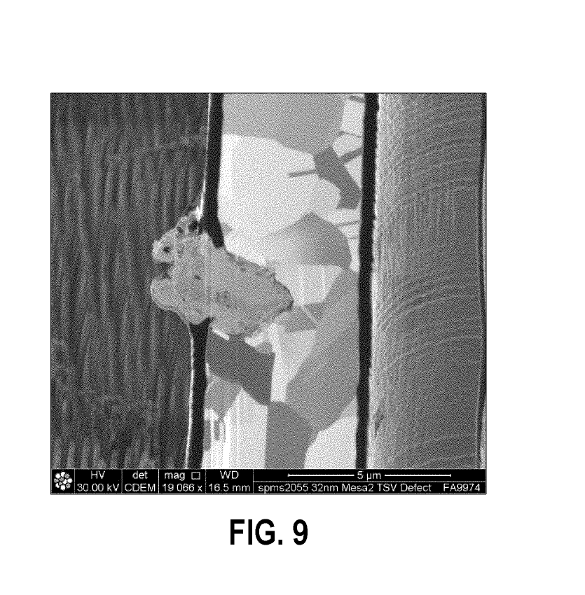

FIG. 9 is a secondary-electron micrograph showing a portion of a programmed device structure in one of the arrays that was acquired using a secondary electron microscope. The programmed device structure was sectioned using a focused ion beam. A copper grain projecting from the polycrystalline copper of the metal layer through the liner layer and the insulator layer is evident in FIG. 9.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It will be understood that when an element is described as being “connected” or “coupled” to or with another element, it can be directly connected or coupled to the other element or, instead, one or more intervening elements may be present. In contrast, when an element is described as being “directly connected” or “directly coupled” to another element, there are no intervening elements present. When an element is described as being “indirectly connected” or “indirectly coupled” to another element, there is at least one intervening element present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device structure formed using a substrate comprised of a semiconductor, the device structure comprising:
a first layer comprised of a polycrystalline metal, the polycrystalline metal including plurality of grains; and
a second layer comprised of an electrical insulator, the second layer positioned between the first layer and a portion of the substrate,
wherein at least one of the grains penetrates through the second layer and into the portion of the substrate.

2. The device structure of claim 1 wherein the first layer and the second layer are positioned within a trench having a sidewall that extends into the substrate from a top surface of the substrate.

3. The device structure of claim 2 wherein the second layer is positioned on the sidewall of the trench, and the first layer is a plug positioned inside the trench.

4. The device structure of claim 1 wherein the first layer and the second layer are positioned on a top surface of the substrate.

5. The device structure of claim 1 wherein the polycrystalline metal of the first layer comprises polycrystalline copper.

6. The device structure of claim 5 wherein the polycrystalline copper has a layer thickness in a first range of 1 μm to 15 μm, and a grain size in a second range of 1 μm to 5 μm.

7. The device structure of claim 5 wherein the electrical insulator of the second layer comprises silicon dioxide, and the silicon dioxide has a thickness in a range of 100 nm to 1000 nm.

8. The device structure of claim 1 wherein the device structure includes the portion of the substrate.

9. The device structure of claim 1 further comprising:
a third layer positioned between the first layer and the second layer, the third layer comprised of tantalum, tantalum nitride, titanium, titanium nitride, or a combination thereof,
wherein the at least one of the grains also penetrates through the third layer.

10. The device structure of claim 1 wherein the at least one of the grains penetrates through the second layer at a location of the insulator layer exhibiting breakdown.

11. The device structure of claim 1 wherein the device structure exhibits a negative resistance over a range of currents when biased in inversion mode in an operating circuit.

12. The device structure of claim 11 wherein a voltage-current curve characterizing the negative resistance has a peak-to-valley ratio in a range from 1.25 to 4 at room temperature.

13. The device structure of claim 1 wherein the device structure is a functioning device element in an integrated circuit when biased in inversion mode.

14. A method for forming a device structure, the method comprising:
fabricating a metal-insulator-semiconductor capacitor using a substrate comprised of a semiconductor; and
applying a signal to a metal layer of the metal-insulator-semiconductor capacitor to cause a breakdown of an insulator layer of the metal-insulator-semiconductor capacitor at a location and thereby form the device structure,
wherein the breakdown at the location of the insulator layer causes the device structure to exhibit negative resistance.

15. The method of claim 14 wherein applying the signal to the metal-insulator-semiconductor capacitor comprises:
programming the metal-insulator-semiconductor capacitor with biasing under accumulation mode.

16. The method of claim 14 wherein the signal comprises a ramped programming voltage, and applying the signal to the metal-insulator-semiconductor capacitor comprises:
directing the ramped programming voltage to the metal layer of the metal-insulator-semiconductor capacitor.

17. The method of claim 14 wherein the signal comprises a pulsed programming voltage, and applying the signal to the metal-insulator-semiconductor capacitor comprises:
directing the pulsed programming voltage to the metal layer of the metal-insulator-semiconductor capacitor.

18. The method of claim 14 wherein fabricating the metal-insulator-semiconductor capacitor comprises:
forming a trench in the substrate;
forming the insulator layer on a sidewall of the trench; and
forming the metal layer inside the trench,
wherein the insulator layer is arranged between the metal layer and the substrate adjacent to the trench, and the location of the breakdown is a position along the sidewall of the trench.

19. The method of claim 18 wherein the metal layer is comprised of a polycrystalline metal, and applying the signal to the metal layer of the metal-insulator-semiconductor capacitor comprises:
causing a grain of the polycrystalline metal to penetrate through the insulator layer and into a portion of the substrate at the location of the breakdown.

20. The method of claim 14 wherein the metal layer is comprised of a polycrystalline metal, and applying the signal to the metal layer of the metal-insulator-semiconductor capacitor comprises:
causing a grain of the polycrystalline metal to penetrate through the insulator layer and into a portion of the substrate at the location of the breakdown.
